(19) United States
(12) Patent Application Publication
(10) Pub. No.: US 2025/0183923 A1
(43) Pub. Date: Jun. 5, 2025

(54) ANTENNA-SWITCHED RECEIVER SYSTEM FOR RADAR APPLICATIONS

(71) Applicant: TEXAS INSTRUMENTS INCORPORATED, Dallas, TX (US)

(72) Inventors: Sun Hwan Jang, Allen, TX (US); Krishnanshu Dandu, Plano, TX (US); Venkatesh Srinivasan, Plano, TX (US)

(21) Appl. No.: 18/524,837

(22) Filed: Nov. 30, 2023

(51) Int. Cl. H04B 1/00; H03F 3/24; H04B 1/16

(52) U.S. Cl. CPC H04B 1/0064; H03F 3/245; H04B 1/16; H03F 2200/294; H03F 2200/451

(57) ABSTRACT

Embodiments disclosed herein relate to antenna switching in radar applications. In an example, a system including a first antenna sub-circuit, a second antenna sub-circuit, and a receiver sub-circuit is provided. The first antenna sub-circuit is configured to couple to a first antenna and includes a first balun, a first transistor, and a first low-noise amplifier. The second antenna sub-circuit is configured to couple to a second antenna and includes a second balun, a second transistor, and a second low-noise amplifier. The receiver sub-circuit includes a transformer having a first set of terminals coupled to the first and second low-noise amplifiers and a second set of terminals coupled to a mixer, the mixer, a first amplifier, a second amplifier, and an analog-to-digital converter. The receiver sub-circuit is configured to receive a signal from either the first or second antenna sub-circuit based on a state of the first and second transistors.

### TECHNICAL FIELD

This relates generally to antenna switching, and more particularly, to using a shared receiver channel for multiple antennas.

### BACKGROUND

Radio frequency (RF) signal transmission and reception systems are employed across a wide range of application areas, including telecommunications, telemetry, aerospace applications, wireless data transmission, satellite and radar imaging, and more. Such systems may include receiver circuits that may be used to interface with antennas and receive signals from the antennas. The systems may also include transmitter circuits that may be used to interface with antennas to transmit signals from the antennas to downstream systems.

Various applications may employ receiver channel components to obtain signals from an antenna for processing. Many antenna-receiver solutions exist to capture antenna signals, however, many such solutions utilize one receiver channel per antenna. In other words, each antenna may be coupled with a standalone receiver channel that is included in an individual interconnect with a separate local oscillator. These solutions may require relatively larger amounts of silicon area, consume higher power, and thus, have higher costs.

Various other solutions may employ switching elements to utilize multiple antennas per single receiver channel, which may reduce silicon area requirements and cost relative to non-switching architectures. One example switching technique includes the use of a single-pole multiple-throw (SPMT) to couple one of multiple antennas to a single shared receiver channel. This technique may reduce the amount of silicon area, however, it may introduce problems such as high RF front-end loss, poor isolation among antennas, and so on when receiving antenna signals as a single receiver channel is used for multiple antennas. Another example switching technique includes the use of switches following the mixers of receiver channels. This technique may improve RF front-end noise performance and isolation, however, it may consume more power and silicon area than other switching techniques.

### SUMMARY

Various embodiments disclosed herein relate to antenna switching in radar receiver systems, and more particularly, to using a shared receiver sub-circuit to interface with multiple antenna interfacing sub-circuits that receive signals from respective antennas. An antenna switching system may include multiple antenna sub-circuits, each antenna sub-circuit capable of interfacing with an individual antenna and receiving signals from a respective antenna. Each of the antenna sub-circuits can further couple to the receiver sub-circuit. However, a switching mechanism can be included in each of the antenna sub-circuits prior to a low-noise amplifier, such that the receiver sub-circuit only receives a signal from one of the antenna sub-circuits.

In an example, a system including a first antenna sub-circuit, a second antenna sub-circuit, and a receiver sub-circuit is provided. The first antenna sub-circuit is configured to couple to a first antenna and includes a first balun, a first transistor, and a first low-noise amplifier. The second antenna sub-circuit is configured to couple to a second antenna and includes a second balun, a second transistor, and a second low-noise amplifier. The receiver sub-circuit includes a transformer having a first set of terminals coupled to the first and second low-noise amplifiers and a second set of terminals coupled to a mixer, the mixer, a first amplifier, a second amplifier, and an analog-to-digital converter. The receiver sub-circuit is configured to receive a signal from either the first or second antenna sub-circuit based on a state of the first and second transistors.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an antenna receiver system that may be used in accordance with an embodiment.

FIG. 2 illustrates an antenna receiver system that may be used in accordance with an embodiment.

FIG. 3 illustrates a transceiver and receiver system that may be used in accordance with an embodiment.

FIG. 4 illustrates an example graphical representation related to gain produced by an antenna receiver system in accordance with an embodiment.

FIG. 5 illustrates an example graphical representation related to noise produced by an antenna receiver system in accordance with an embodiment.

FIG. 6 illustrates an example graphical representation related to power produced by an antenna receiver system in accordance with an embodiment.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Discussed herein are enhanced components, techniques, and systems related to antenna switching in receiver and transceiver systems. Often, RF and radar circuits are designed to receive and transmit signals at varying frequencies and with variable gain from more than one antenna. For example, RF circuits use antenna signals as inputs and use electronic components to output different signals, such as at different bandwidths, to downstream systems, sometimes using the same or different antennas. However, to save silicon area and cost, many systems include a single receiver channel capable of processing incoming radar signals from multiple antennas. Thus, antenna switching components may be implemented to switch between antennas to process certain data at a given time.

Existing antenna switching designs may use switching elements before any processing circuitry or after mixing circuitry. However, the first of these solutions may fail to isolate each channel, add loss to RF front-end, and incur poor signal-to-noise ratio (SNR) despite saving design space and cost. The latter of these solutions may improve on channel-to-channel (i.e., antenna channel to antenna channel) isolation as well as SNR but may occupy large silicon area and consume increased amounts of power during operation. Thus, an antenna switching circuit is needed that can provide isolation and gain sufficient to de-sense noise in the system, match the impedance of the antenna signal, and minimize power consumption and design area requirements.

Disclosed herein is an antenna switching system that includes individual antenna-signal receiving sub-circuits, each having a respective differential low-noise amplifier (LNA), and a shunt transistor switch between the differential inputs of the LNA, and a combined receiver sub-circuit capable of mixing the received signals and converting the received signals into digital signals. The transistors can operate as open switches or closed switches based on signals applied to control gates of the transistors. When one transistor is in an open state, the other transistor may be in a closed state. When a transistor is “ON,” or in the closed state, the antenna signals may not flow to the respective LNA. On the other hand, the transistor of the other antenna-signal receiving sub-circuit may be in an “OFF,” or open state, and its respective LNA may be active to amplify and impedance-match the received signals. Only the active LNA can operate and provide such signals to the receiver sub-circuit for further processing, such as mixing and converting. Advantageously, the disclosed system can enable one antenna and the corresponding antenna sub-circuits at a time, which may decrease power consumption, reduce noise, and increase antenna-channel isolation, and mix and convert antenna signals using a single shared receiver sub-circuit, which may reduce design area required while improving gain and band matching, among other benefits.

In an example embodiment, a system including a first antenna sub-circuit, a second antenna sub-circuit, and a receiver sub-circuit is provided. The first antenna sub-circuit is configured to couple to a first antenna and includes a first balun, a first transistor, and a first low-noise amplifier. The second antenna sub-circuit is configured to couple to a second antenna and includes a second balun, a second transistor, and a second low-noise amplifier. The receiver sub-circuit includes a transformer having a first set of terminals coupled to the first and second low-noise amplifiers and a second set of terminals coupled to a mixer, the mixer, a first amplifier, a second amplifier, and an analog-to-digital converter. The receiver sub-circuit is configured to receive a signal from either the first or second antenna sub-circuit based on a state of the first and second transistors.

In another example embodiment, a system including a first antenna, a second antenna, a first antenna sub-circuit, a second antenna sub-circuit, and a receiver sub-circuit is provided. The first antenna sub-circuit is configured to couple to the first antenna and includes a first balun, a first transistor, and a first low-noise amplifier. The second antenna sub-circuit is configured to couple to the second antenna and includes a second balun, a second transistor, and a second low-noise amplifier. The receiver sub-circuit includes a transformer having a first set of terminals coupled to the first and second low-noise amplifiers and a second set of terminals coupled to a mixer, the mixer, a first amplifier, a second amplifier, and an analog-to-digital converter. The receiver sub-circuit is configured to receive a signal from either the first or second antenna sub-circuit based on a state of the first and second transistors.

In yet another example embodiment, a system including a receiver circuit and a transceiver circuit is provided. The receiver circuit is configured to couple to a first antenna and a second antenna, and the transceiver circuit is configured to couple to a third antenna and to the receiver circuit. The receiver circuit includes a first antenna sub-circuit, a second antenna sub-circuit, and a receiver sub-circuit. The first antenna sub-circuit includes a first balun, a first transistor, and a first low-noise amplifier. The second antenna sub-circuit includes a second balun, a second transistor, and a second low-noise amplifier. The receiver sub-circuit includes a transformer having a first set of terminals coupled to the first and second low-noise amplifiers and a second set of terminals coupled to a mixer, the mixer, a first amplifier, a second amplifier, and an analog-to-digital converter. The receiver sub-circuit is configured to receive a signal from either the first or second antenna sub-circuit based on a state of the first and second transistors. The transceiver circuit is configured to receive a mixed signal from the mixer of the receiver sub-circuit and transmit the mixed signal via the third antenna.

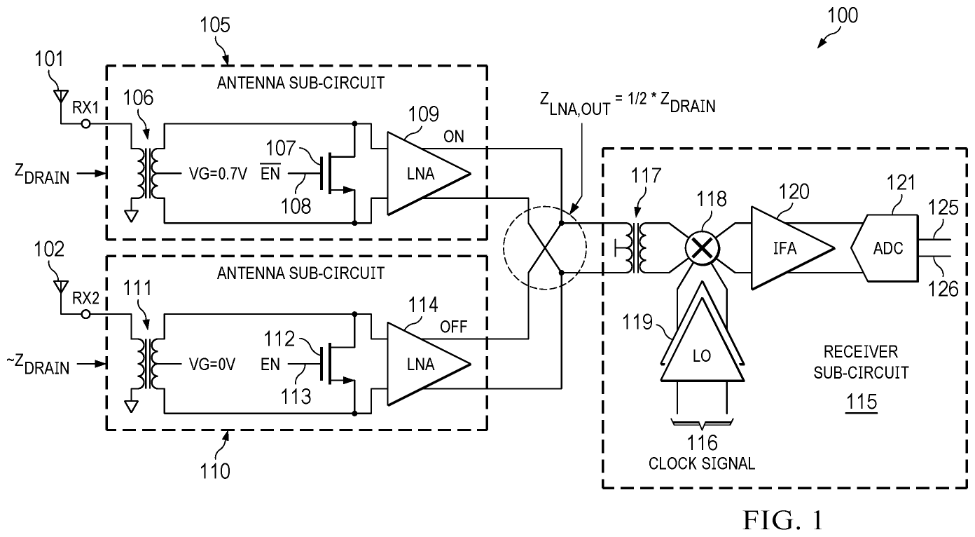

FIG. 1 illustrates an antenna receiver system that may be used in accordance with an embodiment. FIG. 1 includes system 100, which includes antenna 101, antenna 102, antenna sub-circuit 105, antenna sub-circuit 110, and receiver sub-circuit 115. Antenna sub-circuit 105 includes balun 106, transistor 107, and low-noise amplifier (LNA) 109. Antenna sub-circuit 110 includes balun 111, transistor 112, and LNA 114. Receiver sub-circuit 115 includes transformer 117, mixer 118, local oscillator buffer amplifiers 119, intermediate frequency (IF) amplifier 120, and analog-to-digital converter (ADC) 121.

System 100 is representative of a circuit capable of receiving signals from antennas 101 and 102, selectively enabling one of antenna sub-circuits 105 and 110 to amplify a signal from a respective antenna, providing the amplified signal to receiver sub-circuit 115 using the enabled one of antenna sub-circuits 105 or 110, and processing and converting the amplified signal into a digital signal. For example, each of antenna sub-circuits 105 and 110 may include switches (transistor 107 and transistor 112, respectively) that can be opened or closed to enable use of one of antenna sub-circuits 105 or 110. Accordingly, system 100 may enable antenna switching using a shared receiver sub-circuit 115 for antenna sub-circuits 105 and 110.

Antennas 101 and 102 are representative of antennas capable of receiving signals from a radio, satellite, or other device, and converting the signals to electrical currents provided to components of system 100. Antennas 101 and 102 may operate in various bandwidths and radio frequencies. Antennas 101 and 102 may also be capable of transmitting signals to a radio, satellite, or other device.

In system 100, antenna sub-circuit 105 is configured to couple to antenna 101, and antenna sub-circuit 110 is configured to couple to antenna 102. In various examples, antenna sub-circuits 105 and 110 may be part of system-on-chip (SoC). Antennas 101 and 102 may be coupled with components of antenna sub-circuits 105 and 110, respectively, via pins, ports, or other connection points of the package. Accordingly, antennas 101 and 102 may be off-chip or on-package. Additional antennas and antenna sub-circuits may be included in other examples.

Antenna sub-circuit 105 includes balun 106, transistor 107, and LNA 109, and similarly, antenna sub-circuit 110 includes balun 111, transistor 112, and LNA 114. Baluns 106 and 111 may be representative of electrical devices that can provide an interface between antenna 101 and antenna 102, respectively, and other components of antenna sub-circuit 105 and antenna sub-circuit 110, respectively. Baluns 106 and 111 may be configured to provide the other components with a differential signal (i.e., a first signal and a second signal of opposite polarity relative to the first signal) based on the signals received from respective antennas. Baluns 106 and 111 may each include two inductors forming a DC de-coupling between the single-ended input and differential outputs that can provide electrostatic discharge (ESD), match the impedance of the antenna signals, and create a positive and negative signal based on the antenna signals. The inductors of baluns 106 and 111 each have two terminals. A first inductor of balun 106 may have a first terminal configured to couple to antenna 101 and a second terminal configured to couple to a ground node. A second inductor of balun 106 may include a first terminal coupled to a drain of transistor 107 and a second terminal coupled to a source of transistor 107. The second inductor may further include a center-tap node that can be coupled to receive a DC bias voltage (e.g., 0.7 V when in an “ON” state) for LNA 109. Similarly, a first inductor of balun 111 may have a first terminal configured to couple to antenna 102 and a second terminal configured to couple to a ground node. A second inductor of balun 111 may include a first terminal coupled to a drain of transistor 112 and a second terminal coupled to a source of transistor 112. The second inductor may further include a center-tap node that can be coupled to receive a different DC bias voltage (e.g., 0 V when in an “OFF” state) for LNA 114.

Transistors 107 and 112 may be n-type metal-oxide semiconductor field effect transistors (MOSFETs), however, other types of transistors may be included in system 100. Accordingly, transistors 107 and 112 each include a gate, a drain, and a source. Transistor 107 may receive a positive signal from balun 106 at the drain and a negative signal from balun 106 at the source. The drain of transistor 107 may further be coupled to a first input of LNA 109, and the source of transistor 107 may be further coupled to a second input of LNA 109. The gate of transistor 107 may be coupled to a controller, processor, or other control device or logic device capable of providing a signal to the gate of transistor 107. Transistor 112 may receive a positive signal from balun 111 at the drain and a negative signal from balun 111 at the source. The drain of transistor 112 may further be coupled to a first input of LNA 114, and the source of transistor 112 may be further coupled to a second input of LNA 114. The gate of transistor 112 may also be coupled to a controller, processor, or other control device or logic device capable of providing a signal to the gate of transistor 112.

In various examples, a processor (e.g., a CPU) can provide an inverted enable signal 108 to the gate of transistor 107 and a non-inverted version of the enable signal 113 to the gate of transistor 112. Inverted enable signal 108 may have a first value, and enable signal 113 may have a second value opposite relative to the first value. In other words, inverted enable signal 108 and enable signal 113 are opposite with respect to each other. The value of inverted enable signal 108 may influence the operations of transistor 107 such that when inverted enable signal 108 has a value of 0, transistor 107 may operate in an open state, or as an open switch, and the respective balun 106 is able to provide a non-zero differential signal to LNA 109. However, when the value of inverted enable signal 108 has a value of 1, transistor 107 may operate in a closed state, or as a closed switch, and current flow through the transistor 107 may prevent the balun 106 from providing a non-zero differential signal to LNA 109. The value of enable signal 113 may influence the operations of transistor 112 such that when enable signal 113 has a value of 0, transistor 112 may operate in the open state, or as an open switch, and the respective balun 111 is able to provide a non-zero differential signal to LNA 114. However, when the value of enable signal 113 has a value of 1, transistor 112 may operate in the closed state, or as a closed switch, current flow through transistor 112 may prevent the balun 111 from providing a non-zero differential signal to LNA 114. Because inverted enable signal 108 and enable signal 113 have opposite values, it follows that only one of LNAs 109 and 114 may be active or operating at a time. Thus, transistors 107 and 112 can be used as switching elements that dictate which antenna sub-circuit provides signals to receiver sub-circuit 115.

LNAs 109 and 114 are representative of low-noise amplifiers capable of amplifying the differential signals from balun 106 and balun 111, respectively, while minimizing degradation of the signal-to-noise ratio of the antenna signals and matching the impedance of the differential signals to improve power transmission of the differential signals. In various examples, LNAs 109 and 114 may be configured to operate in a common-source configuration.

LNAs 109 and 114 may each include two output ports coupled to transformer 117 of receiver sub-circuit 115. More specifically, transformer 117 may have a first set of terminals and a second set of terminals. The first set of terminals may include a first end and a second end, and the second set of terminals may include a first end and a second end. First output ports of LNAs 109 and 114 can be coupled to the first end of the first set of terminals of transformer 117. Second output ports of LNAs 109 and 114 can be coupled to the second end of the first set of terminals of transformer 117.

In operation, either LNA 109 or LNA 114 may provide differential signals to transformer 117 of receiver sub-circuit 115 based on the states of transistors 107 and 112, or in other words, based on the values of inverted enable signal 108 and enable signal 113.

Receiver sub-circuit 115 is representative of a receiver channel in system 100 that can be configured to receive signals from either antenna sub-circuit 105 or antenna sub-circuit 110, mix, down-convert, amplifier, and the like, the signals, and provide the signals downstream to other systems or sub-circuits (e.g., a digital signal processor, a differential front-end) (not shown). In various examples, receiver sub-circuit 115 may include transformer 117, mixer 118, local oscillator buffer amplifiers 119, IF amplifier 120, and ADC 121.

As mentioned, transformer 117 includes a first set of terminals and a second set of terminals, each set of terminals including a first end and a second end. The second set of terminals may be coupled to mixer 118. Mixer 118 is representative of an electronic device capable of combining two or more different differential signals into combined differential signals, such as a differential signal from one of LNAs 109 or 114 and a differential signal from local oscillator buffer amplifier 119. More specifically, local oscillator buffer amplifier 119 may be coupled to receive clock signal 116 from a local oscillator (not shown). Clock signal 116 may be a differential clock signal that can be fed to inputs of local oscillator buffer amplifier 119. Local oscillator buffer amplifiers 119 may include an intermediate frequency amplifier or another type of amplifier. Local oscillator buffer amplifiers 119 can amplify or convert clock signal 116 and provide clock signal 116 to mixer 118. Mixer 118 can then combine clock signal 116 with the differential signals received at transformer 117. In various examples, mixer 118 may operate as a downconverter, however, in other examples, mixer 118 may be used as an upconverter.

Mixer 118 may further be coupled to IF amplifier 120. IF amplifier 120 may be configured to further amplify the down-converted differential signals in receiver sub-circuit 115. IF amplifier may include two output ports coupled to two input ports of ADC 121 and can provide the signals to ADC 121.

ADC 121 is included in receiver sub-circuit 115 to convert the modulated and mixed differential signals from analog to digital. ADC 121 may convert the positive signal into output 125 and the negative signal into output 126. ADC 121 may provide outputs 125 and 126 downstream.

In various examples, system 100 may be used in applications with time-division multiplexing. For example, enable signal 113 and inverted enable signal 108 may be provided to transistors 112 and 107, respectively, at fixed, sequential time periods. More specifically, first values of the signals may be provided at a first time to receive signals from antenna 101 via antenna sub-circuit 105, then, second values of the signals may be provided at a second time to receive signals from antenna 102 via antenna sub-circuit 110. In such examples, the time periods may be pre-determined values provided to the processor enabling the antenna sub-circuits. In some cases, however, the time periods may be target-specific, antenna-specific, or dynamically changed based on desired capture of radar data of antennas 101 and 102.

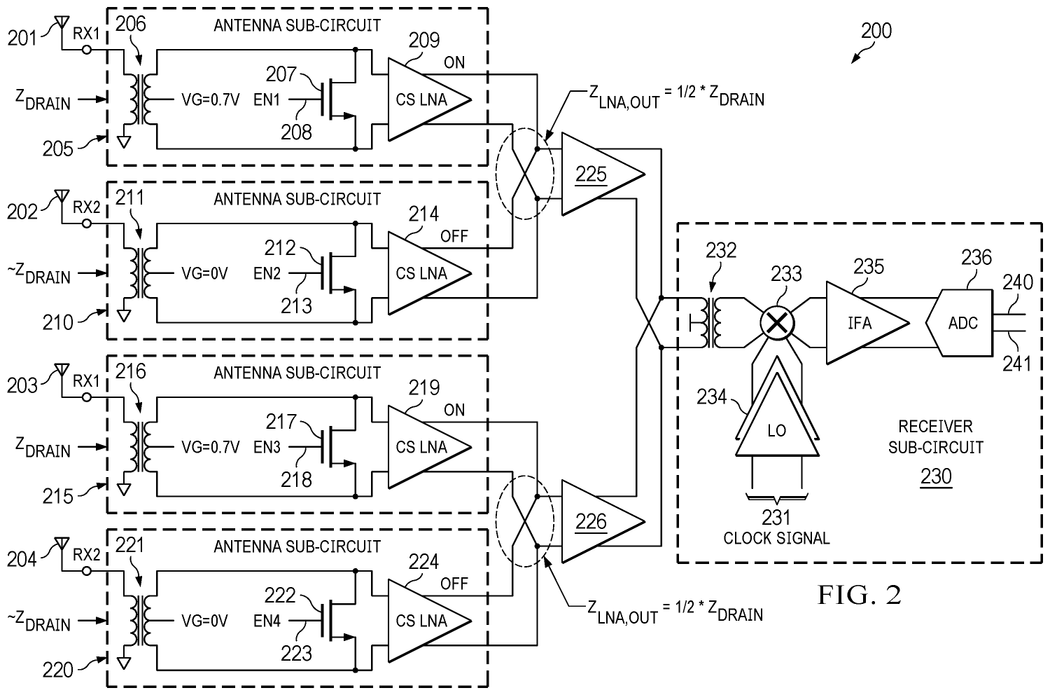

FIG. 2 illustrates an antenna receiver system that may be used in accordance with an embodiment. FIG. 2 includes system 200, which includes antennas 201, 202, 203, and 204, antenna sub-circuits 205, 210, 215, and 220, and receiver sub-circuit 230. Antenna sub-circuit 205 includes balun 206, transistor 207, and low-noise amplifier (LNA) 209. Antenna sub-circuit 210 includes balun 211, transistor 212, and LNA 214. Antenna sub-circuit 215 includes balun 216, transistor 217, and LNA 219. Antenna sub-circuit 220 includes balun 221, transistor 222, and LNA 224. Receiver sub-circuit 230 includes transformer 232, mixer 233, local oscillator buffer amplifiers 234, intermediate frequency (IF) amplifier 235, and analog-to-digital converter (ADC) 236.

System 200 is representative of a circuit capable of receiving signals from antennas 201, 202, 203, and 204, selectively enabling one of antenna sub-circuits 205, 210, 215, and 220 to amplify a signal from a respective antenna, providing the amplified signal to receiver sub-circuit 230 using the enabled one of the antenna sub-circuits and processing and converting the amplified signal into a digital signal. For example, each of antenna sub-circuits 205, 210, 215, and 220 may include switches (transistor 207, transistor 212, transistor 217, and transistor 222, respectively) that can be opened or closed to enable use of one of antenna sub-circuits 205, 210, 215, or 220. Accordingly, system 200 may enable antenna switching using a shared receiver sub-circuit 230 among four different antennas.

Antennas 201, 202, 203, and 204 are representative of antennas capable of receiving signals from a radio, satellite, or other device, and converting the signals to electrical currents provided to components of system 200. Each of the antennas may operate in various bandwidths and radio frequencies. Antennas 201, 202, 203, and 204 may also be capable of transmitting signals to a radio, satellite, or other device.

In system 200, antenna sub-circuit 205 is configured to couple to antenna 201, antenna sub-circuit 210 is configured to couple to antenna 202, antenna sub-circuit 215 is configured to couple to antenna 203, and antenna sub-circuit 220 is configured to couple to antenna 204. In various examples, all of the antenna sub-circuits may be part of a system-on-chip (SoC). Antennas 201, 202, 203, and 204 may be coupled with components of antenna sub-circuits 205, 210, 215, and 220, respectively, via pins, ports, or other connection points of the circuit board. Accordingly, antennas 201, 202, 203, and 204 may be off-chip or on-package. Additional or fewer antennas and antenna sub-circuits may be included in other examples.

Antenna sub-circuit 205 includes balun 206, transistor 207, and LNA 209, antenna sub-circuit 210 includes balun 211, transistor 212, and LNA 214, antenna sub-circuit 215 includes balun 216, transistor 217, and LNA 219, and antenna sub-circuit 220 includes balun 221, transistor 222, and LNA 224. Baluns 206, 211, 216, and 221 (collectively referred to as baluns) may be representative of electrical devices that can provide an interface between antenna 201, antenna 202, antenna 203, and antenna 204 respectively, and other components of respective antenna sub-circuits. The baluns may be configured to provide the other components with a differential signal (i.e., a first signal and a second signal of opposite polarity relative to the first signal) based on the signals received from respective antennas. The baluns may each include two inductors forming a DC de-coupling between the single-ended input and differential outputs that can provide electrostatic discharge (ESD), match the impedance of the antenna signals, and create a positive and negative signal based on the antenna signals. The inductors of the baluns each have two terminals. A first inductor of balun 206 may have a first terminal configured to couple to antenna 201 and a second terminal configured to couple to a ground node. A second inductor of balun 206 may include a first terminal coupled to a drain of transistor 207 and a second terminal coupled to a source of transistor 207. The second inductor may further include a center-tap node that can be coupled to receive a DC bias voltage (e.g., 0.7 V). A first inductor of balun 211 may have a first terminal configured to couple to antenna 202 and a second terminal configured to couple to a ground node. A second inductor of balun 211 may include a first terminal coupled to a drain of transistor 212 and a second terminal coupled to a source of transistor 212. The second inductor may further include a center-tap node that can be coupled to receive a different DC bias voltage. A first inductor of balun 216 may have a first terminal configured to couple to antenna 203 and a second terminal configured to couple to a ground node. A second inductor of balun 216 may include a first terminal coupled to a drain of transistor 217 and a second terminal coupled to a source of transistor 217. The second inductor may further include a center-tap node that can be coupled to receive a different DC bias voltage. A first inductor of balun 221 may have a first terminal configured to couple to antenna 204 and a second terminal configured to couple to a ground node. A second inductor of balun 221 may include a first terminal coupled to a drain of transistor 222 and a second terminal coupled to a source of transistor 222. The second inductor may further include a center-tap node that can be coupled to receive a different DC bias voltage.

Each of the transistors may be n-type metal-oxide semiconductor field effect transistors (MOSFETs), however, other types of transistors may be included in system 200. Accordingly, each of the transistors includes a gate, a drain, and a source. Each of the transistors may receive a positive signal from a respective balun at its drain and a negative signal from the respective balun at its source. The drains of the transistors may be further coupled to a first input of a respective LNA (one of LNAs 209, 214, 219, or 224), and the sources of the transistors may be further coupled to a second input of the respective LNA.

The gate of the transistors may be coupled to a controller, processor, or other control device or logic device capable of providing respective enable signals to the gates (e.g., EN1, EN2, EN3, EN4). In various examples, a processor (e.g., a CPU) can enable either signal 208, 213, 218, or 223 at the gates of the transistors. For example, the processor may provide signal 208 to transistor 207, signal 213 to transistor 212, signal 218 to transistor 217, and signal 223 to transistor 222. In some cases, the signals may be configured such that only one of antenna sub-circuits 205, 210, 215, and 220 operate at a time (e.g., the set of enable signals may be one-hot).

The values of the signals provided to the transistors may influence operations of the transistors. For example, the value of signal 208 may influence the operations of transistor 207 such that when signal 208, or EN1, has a value of 0, transistor 207 may operate in an open state, or as an open switch, and the respective balun 206 is able to provide a non-zero differential signal to LNA 209. However, when the value of signal 208 has a value of 1, transistor 207 may operate in a closed state, or as a closed switch, and current flow through transistor 207 may prevent balun 206 from providing a non-zero differential signal to LNA 209. The value of signal 213 may influence the operations of transistor 212 such that when signal 213, or EN2, has a value of 1, transistor 212 may operate in the closed state, or as a closed switch, and the respective balun 211 is able to provide a non-zero differential signal to LNA 214. However, when the value of signal 213 has a value of 0, transistor 207 may operate in the open state, or as an open switch, and current flow through transistor 212 may prevent the balun 211 from providing a non-zero differential signal to LNA 214. Similarly, signal 218, or EN3, and signal 223, EN4, may control operations and states of transistors 217 and 222, respectively. In various examples, only one of signals 208, 213, 218, and 223 may have a value of “0” at a given time, thus, it follows that only one of LNAs 209, 214, 219, or 224 may be active, or operating, at a time while the others may be inactive. Thus, transistors 207, 212, 217, and 222 can be used as switching elements that dictate which antenna sub-circuit provides signals to amplifiers 225 and 226.

LNAs 209, 214, 219, and 224 (collectively the LNAs) are representative of low-noise amplifiers capable of amplifying the differential signals from respective baluns, while minimizing degradation of the signal-to-noise ratio of the antenna signals and matching the impedance of the differential signals to improve power transmission of the differential signals. In various examples, each of the LNAs may be configured to operate in a common-source configuration.

The LNAs may each include two output ports coupled to input ports of either amplifier 225 or amplifier 226. For example, LNAs 209 and 214 may be coupled to amplifier 225, and LNAs 219 and 224 may be coupled to amplifier 226. Amplifiers 225 and 226 may be included to further amplify the differential signals from the antenna sub-circuits. Amplifiers 225 and 226 may increase RF front-end gain and improve the noise figure of the receiver channel, among other benefits. Amplifiers 225 and 226 may be coupled to transformer 232 of receiver sub-circuit 230.

Transformer 232 may have a first set of terminals and a second set of terminals. The first set of terminals may include a first end and a second end, and the second set of terminals may include a first end and a second end. First output ports of amplifiers 225 and 226 may be coupled to the first end of the first set of terminals and second output ports of amplifiers 225 and 226 may be coupled to the second end of the first set of terminals.

In operation, one of amplifiers 225 or 226 may provide signals from one of the LNAs to transformer 232 of receiver sub-circuit 230 based on the states of the transformers, or in other words, based on the values of signals 208, 213, 218, and 223.

Receiver sub-circuit 230 is representative of a receiver channel in system 200 that can be configured to receive signals from one of antenna sub-circuits 205, 210, 215, or 220, mix, down-convert, amplifier, and the like, the signals, and provide the signals downstream to other systems or sub-circuits (e.g., a digital signal processor, a differential front-end) (not shown). In various examples, receiver sub-circuit 230 may include transformer 232, mixer 233, local oscillator buffer amplifiers 234, IF amplifier 235, and ADC 236.

As mentioned, transformer 232 includes a first set of terminals and a second set of terminals, each set of terminals including a first end and a second end. The second set of terminals may be coupled to mixer 233. Mixer 233 is representative of an electronic device capable of combining two different differential signals into combined differential signals, such as a differential signal from one of amplifiers 225 and 226 and a differential signal from local oscillator buffer amplifiers 234. More specifically, local oscillator buffer amplifiers 234 may be coupled to receive clock signal 231 from a local oscillator (not shown). Clock signal 231 may be a differential clock signal that can be fed to inputs of local oscillator buffer amplifiers 234. Local oscillator buffer amplifiers 234 may include an intermediate frequency amplifier or another type of amplifier. Local oscillator buffer amplifiers 234 can amplify clock signal 231 and provide clock signal 231 to mixer 233. Mixer 233 can then combine clock signal 231 with the differential signals received at transformer 232. In various examples, mixer 233 may operate as a downconverter, however, in other examples, mixer 233 may be used as an upconverter.

Mixer 233 may further be coupled to IF amplifier 235. IF amplifier 235 may be configured to further amplify the down-converted differential signals in receiver sub-circuit 230. IF amplifier may include two output ports coupled to two input ports of ADC 236 and can provide the signals to ADC 236.

ADC 236 is included in receiver sub-circuit 230 to convert the modulated and mixed differential signals from analog to digital. ADC 236 may convert the positive signal into output 240 and the negative signal into output 241. ADC 236 may provide outputs 240 and 241 downstream.

In some examples, system 200 may include additional receiver sub-circuits. For example, a system may include two receiver sub-circuits. One receiver sub-circuit may be used to process antenna signals from antenna sub-circuits 205 and 210, and a second receiver sub-circuit may be used to process antenna signals from antenna sub-circuits 215 and 220. Any combination or variation of antenna sub-circuits and receiver sub-circuits may be included in a system.

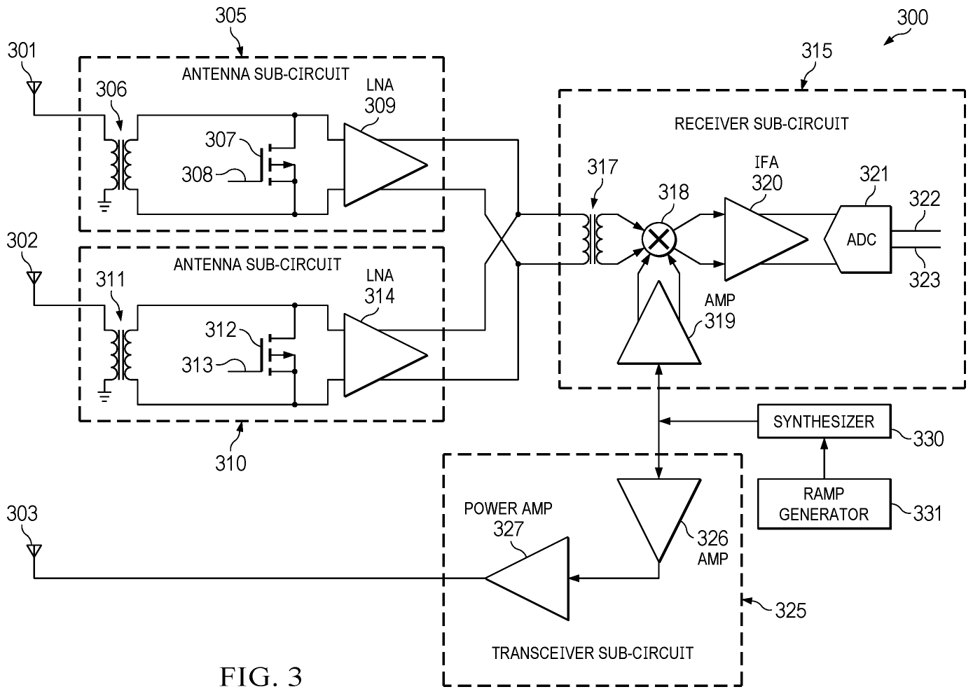

FIG. 3 illustrates a transceiver and receiver system that may be used in accordance with an embodiment. FIG. 3 includes system 300, which includes antennas 301, 302, and 303, antenna sub-circuits 305 and 310, receiver sub-circuit 315, synthesizer 330, ramp generator 331, and transmitter sub-circuit 325. Antenna sub-circuit 305 includes balun 306, transistor 307, and low-noise amplifier (LNA) 309. Antenna sub-circuit 310 includes balun 311, transistor 312, and LNA 314. Receiver sub-circuit 315 includes transformer 317, mixer 318, local oscillator buffer amplifier 319, intermediate frequency (IF) amplifier 320, and analog-to-digital converter (ADC) 321. Transmitter sub-circuit 325 includes local oscillator buffer amplifier 326 and power amplifier 327.

System 300 is representative of a circuit capable of receiving signals from antennas 301 and 302 and transmitting signals from antenna 303. Components of system 300 can selectively enable one of antenna sub-circuits 305 and 310 to amplify a signal from a respective antenna, provide the amplified signal to receiver sub-circuit 315, process the amplified signal into a digital signal, and further provide the amplified signal to transmitter sub-circuit 325. For example, each of antenna sub-circuits 305 and 310 may include switches (transistor 307 and transistor 312, respectively) that can be opened or closed to enable use of one of antenna sub-circuits 305 or 310. Accordingly, system 300 may enable antenna switching using a shared receiver sub-circuit 315 for antenna sub-circuits 305 and 310.

Antennas 301, 302, and 303 are representative of antennas capable of receiving or transmitting signals from a radio, satellite, or other device, and converting the signals to electrical currents provided to components of system 300. The antennas may operate in various bandwidths and radio frequencies.

In system 300, antenna sub-circuit 305 is configured to couple to antenna 301, and antenna sub-circuit 310 is configured to couple to antenna 302. In various examples, antenna sub-circuits 305 and 310 may be on-board and part of a system-on-chip (SoC). For example, antenna sub-circuits 305 and 310 may be on a circuit board. Antennas 301 and 302 may be coupled with components of antenna sub-circuits 305 and 310, respectively, via pins, ports, or other connection points of the circuit board. Accordingly, antennas 301 and 302 may be off-chip. Additional antennas and antenna sub-circuits may be included in other examples.

Antenna sub-circuit 305 includes balun 306, transistor 307, and LNA 309, and similarly, antenna sub-circuit 310 includes balun 311, transistor 312, and LNA 314. Baluns 306 and 311 may be representative of electrical devices that can provide an interface between antenna 301 and antenna 302, respectively, and other components of antenna sub-circuit 305 and antenna sub-circuit 310, respectively. Baluns 306 and 311 may be configured to provide the other components with a differential signal (i.e., a first signal and a second signal of opposite polarity relative to the first signal) based on the signals received from respective antennas. The baluns 306 and 311 may each include two inductors forming a DC de-coupling between the single-ended input and differential outputs that can provide electrostatic discharge (ESD), match the impedance of the antenna signals, and create a positive and negative signal based on the antenna signals. The inductors of baluns 306 and 311 each have two terminals. A first inductor of balun 306 may have a first terminal configured to couple to antenna 301 and a second terminal configured to couple to a ground node. A second inductor of balun 306 may include a first terminal coupled to a drain of transistor 307 and a second terminal coupled to a source of transistor 307. The second inductor may further include a center-tap node that can be coupled to receive a DC bias voltage (e.g., 0.7 V). Similarly, a first inductor of balun 311 may have a first terminal configured to couple to antenna 302 and a second terminal configured to couple to a ground node. A second inductor of balun 311 may include a first terminal coupled to a drain of transistor 312 and a second terminal coupled to a source of transistor 312. The second inductor may further include a center-tap node that can be coupled to receive a different DC bias voltage (e.g., 0 V).

Transistors 307 and 312 may be n-type metal-oxide semiconductor field effect transistors (MOSFETs), however, other types of transistors may be included in system 300. Accordingly, transistors 307 and 312 each include a gate, a drain, and a source. Transistor 307 may receive a positive signal from balun 306 at the drain and a negative signal from balun 306 at the source. The drain of transistor 307 may further be coupled to a first input of LNA 309, and the source of transistor 307 may be further coupled to a second input of LNA 309. The gate of transistor 307 may be coupled to a controller, processor, or other control device or logic device capable of providing a signal to the gate of transistor 307. Transistor 312 may receive a positive signal from balun 311 at the drain and a negative signal from balun 311 at the source. The drain of transistor 312 may further be coupled to a first input of LNA 314, and the source of transistor 312 may be further coupled to a second input of LNA 314. The gate of transistor 312 may also be coupled to a controller, processor, or other control device or logic device capable of providing a signal to the gate of transistor 312.

In various examples, a processor (e.g., a CPU) can provide an inverted enable signal 308 to the gate of transistor 307 and a non-inverted version of the enable signal 313 to the gate of transistor 312. Inverted enable signal 308 may have a first value, and enable signal 313 may have a second value opposite relative to the first value. In other words, inverted enable signal 308 and enable signal 313 are opposite with respect to each other. The value of inverted enable signal 308 may influence the operations of transistor 307 such that when inverted enable signal 308 has a value of 0, transistor 307 may operate in an open state, or as an open switch, and balun 306 is able to provide a non-zero differential signal to LNA 309. However, when the value of inverted enable signal 308 has a value of 1, transistor 307 may operate in a closed state, or as a closed switch, and current flow through transistor 307 may prevent balun 306 from providing a non-zero differential signal to LNA 309. The value of enable signal 313 may influence the operations of transistor 312 such that when enable signal 313 has a value of 1, transistor 312 may operate in the closed state, or as a closed switch, and current flow through transistor 312 may prevent balun 311 from providing a non-zero differential signal to LNA 314. However, when the value of enable signal 313 has a value of 0, transistor 307 may operate in the open state, or as an open switch, and balun 311 is able to provide a non-zero differential signal to LNA 314. Because inverted enable signal 308 and enable signal 313 have opposite values, it follows that only one of LNAs 309 and 314 may be active or operating at a time. Thus, transistors 307 and 312 can be used as switching elements that dictate which antenna sub-circuit provides signals to receiver sub-circuit 315.

LNAs 309 and 314 are representative of low-noise amplifiers capable of amplifying the differential signals from balun 306 and balun 311, respectively, while minimizing degradation of the signal-to-noise ratio of the antenna signals and matching the impedance of the differential signals to improve power transmission of the differential signals. In various examples, LNA 309 may be configured to operate in a common-source configuration.

LNAs 309 and 314 may each include two output ports coupled to transformer 317 of receiver sub-circuit 315. More specifically, transformer 317 may have a first set of terminals and a second set of terminals. The first set of terminals may include a first end and a second end, and the second set of terminals may include a first end and a second end. First output ports of LNAs 309 and 314 can be coupled to the first end of the first set of terminals of transformer 317. Second output ports of LNAs 309 and 314 can be coupled to the second end of the first set of terminals of transformer 317.

In operation, either LNA 309 or LNA 314 may provide differential signals to transformer 317 of receiver sub-circuit 315 based on the states of transistors 307 and 312, or in other words, based on the values of inverted enable signal 308 and enable signal 313.

Receiver sub-circuit 315 is representative of a receiver channel in system 300 that can be configured to receive signals from either antenna sub-circuit 305 or antenna sub-circuit 310, mix, down-convert, amplifier, and the like, the signals, and provide the signals downstream to other systems or sub-circuits (e.g., a digital signal processor, a differential front-end) (not shown). In various examples, receiver sub-circuit 315 may include transformer 317, mixer 318, local oscillator buffer amplifier 319, IF amplifier 320, and ADC 321.

As mentioned, transformer 317 includes a first set of terminals and a second set of terminals, each set of terminals including a first end and a second end. The second set of terminals may be coupled to mixer 318. Mixer 318 is representative of an electronic device capable of combining two or more different differential signals into combined differential signals, such as a differential signal from one of LNAs 309 or 314 and a differential signal from local oscillator buffer amplifier 319. More specifically, local oscillator buffer amplifier 319 may be coupled to receive a clock signal from synthesizer 330. The clock signal may be a differential clock signal generated by ramp generator 331 and fed to receiver sub-circuit 315 by synthesizer 330 that can further be fed to inputs of local oscillator buffer amplifier 319. Local oscillator buffer amplifier 319 can amplify or convert the clock signal and provide the clock signal to mixer 318. Mixer 318 can then combine the clock signal with the differential signals received at transformer 317. In various examples, mixer 318 may operate as a downconverter, however, in other examples, mixer 318 may be used as an upconverter.

Mixer 318 may be coupled to IF amplifier 320. IF amplifier 320 may be configured to further amplify the down-converted differential signals in receiver sub-circuit 315. IF amplifier may include two output ports coupled to two input ports of ADC 321 and can provide the signals to ADC 321.

ADC 321 is included in receiver sub-circuit 315 to convert the modulated and mixed differential signals from analog to digital. ADC 321 may convert the positive signal into output 322 and the negative signal into output 323. ADC 321 may provide outputs 322 and 323 downstream.

Receiver sub-circuit 315 and synthesizer 330 may also be coupled to local oscillator buffer amplifier 326 of transmitter sub-circuit 325. Transmitter sub-circuit 325 is representative of various devices, components, circuits, and the like capable of processing and synchronizing signals from mixer 318 to transmit signals downstream via antenna 303. In an example, components of transmitter sub-circuit 325 form transmission generation circuitry. Transmitter sub-circuit 325 may include local oscillator buffer amplifier 326 and power amplifier 327, among other components not shown.

Synthesizer 330 may include a phase-locked loop (PLL) coupled to local oscillator buffer amplifier 326 of transmitter sub-circuit 325. The PLL is representative of a circuit capable of changing the frequency of a reference signal (e.g., a clock signal) provided by a reference circuit, such as ramp generator 331. For example, the PLL can increase the frequency of the reference signal and provide the reference signal to transmitter sub-circuit 325 and receiver sub-circuit 315.

Ramp generator 331 is representative of a circuit capable of generating frequency modulated continuous wave (FMCW) radar signals for transmission via antenna 303 based on timing information and reference signals provided by a timing circuit or other component (not shown). Ramp generator 331 can provide the FMCW radar signals to synthesizer 330.

Local oscillator buffer amplifier 326 receives signals from synthesizer 330, amplifies the signals, and provides the amplified signals to power amplifier 327. Power amplifier 327 is included to further amplify the signals provided by local oscillator buffer amplifier 326 via synthesizer 330 and ramp generator 331 for transmission via antenna 303. Power amplifier 327 can provide the amplified signals to antenna 303 at a specific time (i.e., a time specified by a timing circuit or other component). Then, antenna 303 can transmit radar signals downstream.

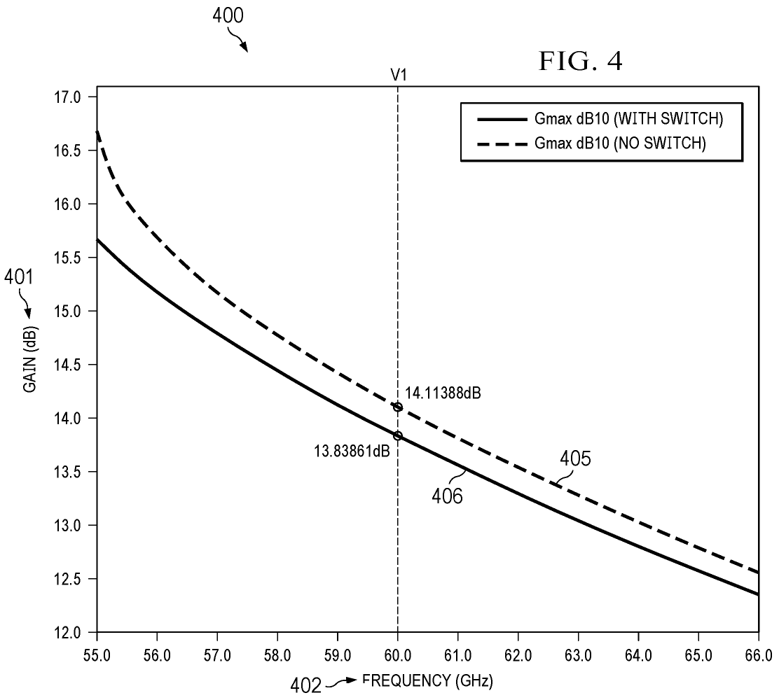

FIG. 4 illustrates an example graphical representation related to maximum gain produced by a low-noise amplifier of an antenna receiver system in accordance with an embodiment. FIG. 4 shows graphical representation 400, which includes sample results of gain 401 with respect to frequency 402 measured at nodes of an antenna receiver system, such as system 100 of FIG. 1, referencing elements of FIG. 1.

Outputs 405 and 406 are representative of sample gain results measured at a first node between balun 106 and transistor 107 (i.e., an input to transistor 107) and at a second node between LNA 109 and receiver sub-circuit 115 (i.e., the output of LNA 109) when a frequency 402 is applied to the first node. Output 405 shows such results in a system without a switch, or without transistor 107 in antenna sub-circuit 105. Output 406 shows such results in a system including transistor 107 in an open state, such as system 100. At various values of frequency 402, values of gain 401 may be slightly lower (e.g., 0.3 dB) in a system including transistor 107 as demonstrated by comparing output 405 and output 406. Thus, antenna switching using transistor 107 as a switch placed before LNA 109 may only have slight impacts on gain 401.

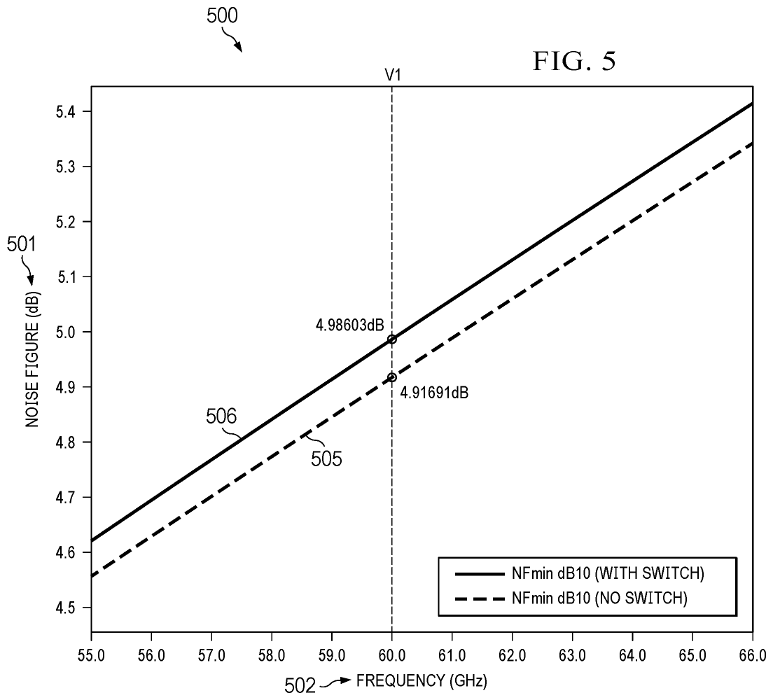

FIG. 5 illustrates an example graphical representation related to noise produced by a low noise amplifier of an antenna-switched receiver system in accordance with an embodiment. FIG. 5 shows graphical representation 500, which includes sample results of minimum achievable noise FIG. 501 with respect to frequency 502 measured at nodes of an antenna receiver system, such as system 100 of FIG. 1, referencing elements of FIG. 1.

Outputs 505 and 506 are representative of sample noise figure results measured at a first node between balun 106 and transistor 107 (i.e., an input to transistor 107) and at a second node between LNA 109 and receiver sub-circuit 115 (i.e., the output of LNA 109) when a frequency 502 is applied to the first node. Output 505 shows such results in a system without a switch, or without transistor 107 in antenna sub-circuit 105. Output 506 shows such results in a system, such as system 100, including transistor 107 in an open state. At various values of frequency 502, values of noise 501 may be slightly higher (e.g., 0.1 dB) in a system including transistor 107 as demonstrated by comparing output 505 and output 506. Thus, antenna switching using transistor 107 as a switch placed before LNA 109 may only have slight impacts on minimum achievable noise FIG. 501.

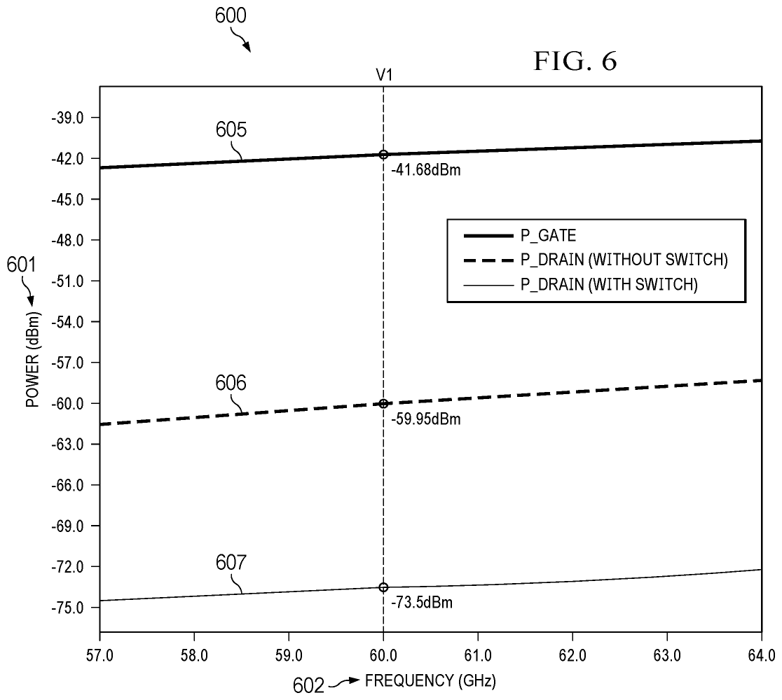

FIG. 6 illustrates an example graphical representation related to power produced by an antenna receiver system in accordance with an embodiment. FIG. 6 shows graphical representation 600, which includes sample results of power 601 with respect to frequency 602 measured at nodes of an antenna receiver system, such as system 100 of FIG. 1, referencing elements of FIG. 1.

Output 605 is representative of power measured at a first node between balun 106 and transistor 107 (i.e., an input to transistor 107). Outputs 606 and 607 are representative of sample power results without and with a transistor 107, respectively, measured at a second node between LNA 109 and receiver sub-circuit 115 (i.e., the output of LNA 109) when a frequency 502 is applied to the first node.

In various examples, isolation may be measured by comparing the power at the second node through antenna sub-circuit 105 and the power at the second node coming through antenna sub-circuit 110 when antenna sub-circuit 105 is “on” (i.e., transistor 107 is in the open state) and antenna sub-circuit 110 is “off” (i.e., transistor 112 is in the closed state). In an ideal situation, no current would flow through antenna sub-circuit 110 when antenna sub-circuit is off, and thus, the isolation between the output at the second node and the input at the first node would be infinite. However, in real situations, leakage signal may flow through LNA 114 to receiver sub-circuit 115, so the value of the isolation may be a real value.

Output 606 demonstrates values of power 601 across varying values of frequency 602 in systems with no switches, or without transistors 107 and 112. The difference in power 601 values between outputs 605 and 606, or the isolation, may be approximately 18.5 dB. Output 607 demonstrates values of power 601 across varying values of frequency 602 in systems with switches, or with transistors 107 and 112, such as system 100. The difference in power 601 values between outputs 605 and 607, or the isolation, may be approximately 31 dB. Accordingly, the use of transistors 107 and 112 placed before LNAs 109 and 114, respectively, in a system may increase the isolation within a system across varying values of frequency 602.

While some examples provided herein are described in the context of an antenna switching system, receiver sub-circuit, antenna sub-circuit, component, device, element, architecture, or environment, the systems, circuits, and methods described herein are not limited to such embodiments and may apply to a variety of other processes, systems, applications, devices, and the like.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or elements are presented in a given order, alternative implementations may perform routines having steps, or employ systems having elements or components, in a different order, and some processes or elements may be deleted, moved, added, subdivided, combined, and/or modified to provide alternative or subcombinations. Each of these processes or elements may be implemented in a variety of different ways. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A system, comprising:
a first antenna sub-circuit configured to couple to a first antenna;
a second antenna sub-circuit configured to couple to a second antenna; and
a receiver sub-circuit coupled to each of the first antenna sub-circuit and the second antenna sub-circuit;
wherein the first antenna sub-circuit comprises:
a first balun configured to couple to the first antenna;
a first transistor coupled to the first balun; and
a first low-noise amplifier coupled to the first transistor;
wherein the second antenna sub-circuit comprises:
a second balun configured to couple to the second antenna;
a second transistor coupled to the second balun; and
a second low-noise amplifier coupled to the second transistor; and
wherein the receiver sub-circuit comprises:
a transformer including a first set of terminals coupled to the first low-noise amplifier and the second low-noise amplifier and a second set of terminals coupled to a mixer;
the mixer coupled to the second set of terminals of the transformer, a first amplifier, and a second amplifier;
the first amplifier coupled to the mixer and to a local oscillator;
the second amplifier coupled to the mixer and to an analog-to-digital converter; and
the analog-to-digital converter.

2. The system of claim 1, wherein:
the first balun includes a first terminal and a second terminal;
the first low-noise amplifier includes a first input coupled to the first terminal of the first balun and a second input coupled to the second terminal of the first balun; and
the first transistor includes:
a drain coupled to the first terminal of the first balun and the first input of the first low-noise amplifier; and
a source coupled to the second terminal of the first balun and the second input of the first low-noise amplifier.

3. The system of claim 2, wherein:
the second balun includes a first terminal and a second terminal;
the second low-noise amplifier includes a first input coupled to the first terminal of the second balun and a second input coupled to the second terminal of the second balun; and
the second transistor includes:
a drain coupled to the first terminal of the second balun and the first input of the second low-noise amplifier; and
a source coupled to the second terminal of the second balun and the second input of the second low-noise amplifier.

4. The system of claim 1, wherein:
the first low-noise amplifier includes a first output coupled to the first set of terminals of the transformer and a second output coupled to the first set of terminals of the transformer; and
the second low-noise amplifier includes a first output coupled to the first output of the first low-noise amplifier and to the first set of terminals of the transformer and a second output coupled to the second output of the second low-noise amplifier and to the first set of terminals of the transformer.

5. The system of claim 1, wherein each of the first and second low-noise amplifiers is configured to operate in a common-source configuration.

6. The system of claim 1, wherein the mixer of the receiver sub-circuit is configured to produce a mixed signal based on an impedance-matched signal from one of the first antenna sub-circuit and the second antenna sub-circuit and a clock signal from the first amplifier via the local oscillator and to provide the mixed signal to the second amplifier.

7. The system of claim 6, wherein the second amplifier is configured to produce an amplified mixed signal based on the mixed signal and to provide the amplified mixed signal to the analog-to-digital converter, wherein the second amplifier is an intermediate frequency amplifier.

8. The system of claim 7, wherein the analog-to-digital converter is configured to produce a digital signal based on the amplified mixed signal and to provide the digital signal downstream.

9. The system of claim 1, further comprising:
a third antenna sub-circuit configured to couple to a third antenna; and
a fourth antenna sub-circuit configured to couple to a fourth antenna;
wherein the third antenna sub-circuit comprises:
a third balun configured to couple to the third antenna;
a third transistor coupled to the third balun; and
a third low-noise amplifier coupled to the third transistor;
wherein the fourth antenna sub-circuit comprises:
a fourth balun configured to couple to the fourth antenna;
a fourth transistor coupled to the fourth balun; and
a fourth low-noise amplifier coupled to the fourth transistor.

10. The system of claim 9, further comprising:
a third amplifier coupled to the first low-noise amplifier of the first antenna sub-circuit, to the second low-noise amplifier of the second antenna sub-circuit, and to the first set of terminals of the transformer of the receiver sub-circuit; and
a fourth amplifier coupled to the third low-noise amplifier of the third antenna sub-circuit, to the fourth low-noise amplifier of the fourth antenna sub-circuit, and to the first set of terminals of the transformer of the receiver sub-circuit.

11. The system of claim 9, wherein:
the third balun includes a first terminal and a second terminal;
the third low-noise amplifier includes a first input coupled to the first terminal of the third balun and a second input coupled to the second terminal of the third balun; and
the third transistor includes:
a drain coupled to the first terminal of the third balun and the first input of the third low-noise amplifier; and
a source coupled to the second terminal of the third balun and the second input of the third low-noise amplifier.

12. The system of claim 11, wherein:
the fourth balun includes a first terminal and a second terminal;
the fourth low-noise amplifier includes a first input coupled to the first terminal of the fourth balun and a second input coupled to the second terminal of the fourth balun; and
the fourth transistor includes:
a drain coupled to the first terminal of the fourth balun and the first input of the fourth low-noise amplifier; and
a source coupled to the second terminal of the fourth balun and the second input of the fourth low-noise amplifier.

13. A system, comprising:
a first antenna;
a second antenna;
a first antenna sub-circuit configured to couple to the first antenna;
a second antenna sub-circuit configured to couple to the second antenna; and
a receiver sub-circuit coupled to each of the first antenna sub-circuit and the second antenna sub-circuit;
wherein the first antenna sub-circuit comprises:
a first balun configured to couple to the first antenna;
a first transistor coupled to the first balun; and
a first low-noise amplifier coupled to the first transistor;
wherein the second antenna sub-circuit comprises:
a second balun configured to couple to the second antenna;
a second transistor coupled to the second balun; and
a second low-noise amplifier coupled to the second transistor; and
wherein the receiver sub-circuit comprises:
a transformer including a first set of terminals coupled to the first low-noise amplifier and the second low-noise amplifier and a second set of terminals coupled to a mixer;
the mixer coupled to the second set of terminals of the transformer, a first amplifier, and a second amplifier;
the first amplifier coupled to the mixer and to a local oscillator;
the second amplifier coupled to the mixer and to an analog-to-digital converter; and
the analog-to-digital converter.

14. The system of claim 13, wherein:
the first balun includes a first terminal and a second terminal;
the first low-noise amplifier includes a first input coupled to the first terminal of the first balun and a second input coupled to the second terminal of the first balun; and
the first transistor includes:
a drain coupled to the first terminal of the first balun and the first input of the first low-noise amplifier; and
a source coupled to the second terminal of the first balun and the second input of the first low-noise amplifier.

15. The system of claim 14, wherein:
the second balun includes a first terminal and a second terminal;
the second low-noise amplifier includes a first input coupled to the first terminal of the second balun and a second input coupled to the second terminal of the second balun; and
the second transistor includes:
a drain coupled to the first terminal of the second balun and the first input of the second low-noise amplifier; and
a source coupled to the second terminal of the second balun and the second input of the second low-noise amplifier.

16. The system of claim 13, wherein:
the first low-noise amplifier includes a first output coupled to the first set of terminals of the transformer and a second output coupled to the first set of terminals of the transformer; and
the second low-noise amplifier includes a first output coupled to the first output of the first low-noise amplifier and to the first set of terminals of the transformer and a second output coupled to the second output of the second low-noise amplifier and to the first set of terminals of the transformer.

17. A system, comprising:
a receiver circuit configured to couple to a first antenna and a second antenna; and
a transceiver circuit configured to couple to a third antenna and coupled to the receiver circuit;
wherein the receiver circuit comprises:
a first antenna sub-circuit configured to couple to the first antenna;
a second antenna sub-circuit configured to couple to the second antenna; and
a receiver sub-circuit coupled to each of the first antenna sub-circuit and the second antenna sub-circuit;
wherein the first antenna sub-circuit comprises:
a first balun configured to couple to the first antenna;
a first transistor coupled to the first balun; and
a first low-noise amplifier coupled to the first transistor;
wherein the second antenna sub-circuit comprises:
a second balun configured to couple to the second antenna;
a second transistor coupled to the second balun; and
a second low-noise amplifier coupled to the second transistor; and
wherein the receiver sub-circuit comprises:
a transformer including a first set of terminals coupled to the first low-noise amplifier and the second low-noise amplifier and a second set of terminals coupled to a mixer;
the mixer coupled to a first amplifier and a second amplifier of the receiver sub-circuit and to a transceiver amplifier of the transceiver circuit;
the first amplifier coupled to the mixer and to a local oscillator;
the second amplifier coupled to the mixer and to an analog-to-digital converter; and
the analog-to-digital converter.

18. The system of claim 17, wherein:
the first balun includes a first terminal and a second terminal;
the first low-noise amplifier includes a first input coupled to the first terminal of the first balun and a second input coupled to the second terminal of the first balun; and
the first transistor includes:
a drain coupled to the first terminal of the first balun and the first input of the first low-noise amplifier; and
a source coupled to the second terminal of the first balun and the second input of the first low-noise amplifier.

19. The system of claim 18, wherein:
the second balun includes a first terminal and a second terminal;
the second low-noise amplifier includes a first input coupled to the first terminal of the second balun and a second input coupled to the second terminal of the second balun; and
the second transistor includes:
a drain coupled to the first terminal of the second balun and the first input of the second low-noise amplifier; and
a source coupled to the second terminal of the second balun and the second input of the second low-noise amplifier.

20. The system of claim 17, wherein:
the first low-noise amplifier includes a first output coupled to the first set of terminals of the transformer and a second output coupled to the first set of terminals of the transformer; and
the second low-noise amplifier includes a first output coupled to the first output of the first low-noise amplifier and to the first set of terminals of the transformer and a second output coupled to the second output of the second low-noise amplifier and to the first set of terminals of the transformer.
